(19) United States
(12) Patent Application Publication
(10) Pub. No.: US 2024/0295024 A1
(43) Pub. Date: Sep. 5, 2024

(54) SUBSTRATE PROCESSING APPARATUS

(71) Applicant: Tokyo Electron Limited, Tokyo (JP)

(72) Inventors: Makoto TAKAHASHI, Iwate (JP); Masato KADOBE, Tokyo (JP); Tatsuya YAMAGUCHI, Tokyo (JP)

(21) Appl. No.: 18/588,315

(22) Filed: Feb. 27, 2024

(30) Foreign Application Priority Data
Mar. 2, 2023 (JP) 2023-031872

(51) Int. Cl. C23C 16/455; C23C 16/48

(52) U.S. Cl. CPC C23C 16/45548; C23C 16/4557; C23C 16/45578; C23C 16/481

(57) ABSTRACT

A substrate processing apparatus includes: a processing container capable of accommodating a substrate holder that holds substrates; a gas supply chamber provided in a side wall of the processing container, a supply-side pipe extending horizontally from the gas supply chamber, and an injector detachably disposed spanning through the gas supply chamber and the supply-side pipe.

### CROSS-REFERENCE TO RELATED APPLICATIONS

This application is based on and claims priority from Japanese Patent Application No. 2023-031872, filed on Mar. 2, 2023, with the Japan Patent Office, the disclosure of which is incorporated herein in its entirety by reference.

### TECHNICAL FIELD

The present disclosure relates to a substrate processing apparatus.

### BACKGROUND

Japanese Patent Laid-Open Publication No. 2012-169307 discloses a longitudinal deposition apparatus, which includes a reaction tube, a flange portion supporting the reaction tube from below, a gas injector inserted into the reaction tube from the flange portion and extending upwardly in the reaction tube, and an exhaust port formed in the flange portion.

### SUMMARY

According to an aspect of the present disclosure, a substrate processing apparatus includes: a processing container body capable of accommodating a substrate holder that holds substrates; a gas supply chamber provided in a side wall of the processing container body; a supply-side pipe extending horizontally from the gas supply chamber; and an injector detachably disposed spanning through the gas supply chamber and the supply-side pipe.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical cross-sectional view illustrating an example of a substrate processing apparatus according to a first embodiment.

FIG. 2 is a horizontal cross-sectional view illustrating an example of the substrate processing apparatus according to the first embodiment.

FIG. 3 is a perspective view illustrating an example of an injector.

FIG. 4 is a perspective view illustrating another example of the injector.

FIG. 5 is a perspective view illustrating an example of the arrangement of pipes and gas injector heaters.

FIG. 6 is a perspective view illustrating an example of a structure of a heating mechanism.

FIG. 7 is a vertical cross-sectional view illustrating an example of a substrate processing apparatus according to a second embodiment.

FIG. 8 is a horizontal cross-sectional view illustrating an example of the substrate processing apparatus according to the second embodiment.

FIG. 9 is a perspective view illustrating an example of an ejector.

FIG. 10 is a cross-sectional view illustrating an example of a seal structure.

FIG. 11 is a vertical cross-sectional view illustrating an example of a substrate processing apparatus according to a third embodiment.

FIG. 12 is a horizontal cross-sectional view illustrating an example of the substrate processing apparatus according to the third embodiment.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for implementing the present disclosure will be described with reference to the drawings. In the respective drawings, the same components will be denoted by the same reference numerals, and overlapping descriptions thereof may be omitted.

### [Substrate Processing Apparatus 100A According to First Embodiment]

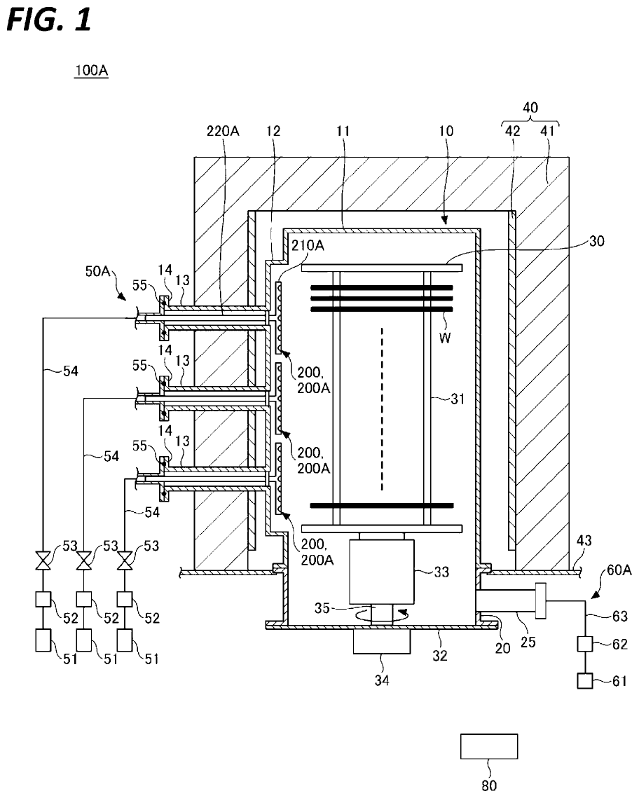

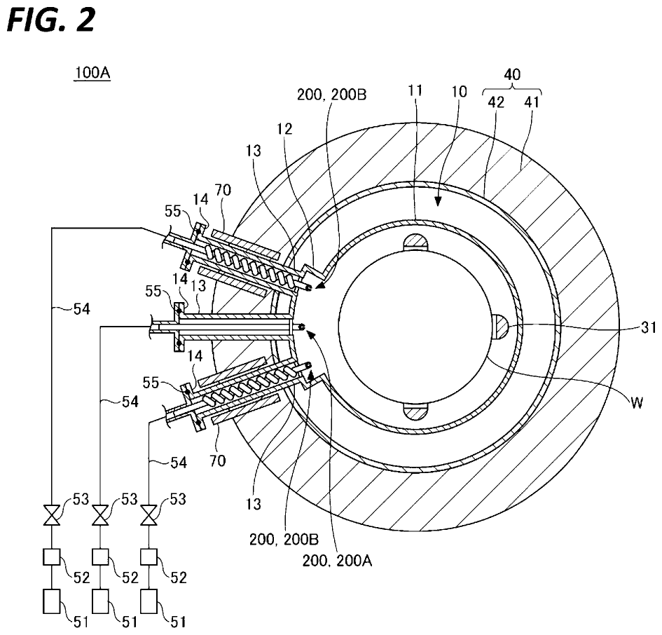

A substrate processing apparatus 100A according to a first embodiment will be described using FIGS. 1 and 2. FIG. 1 is a vertical cross-sectional view illustrating an example of the substrate processing apparatus 100A according to the first embodiment. FIG. 2 is a horizontal cross-sectional view illustrating an example of the substrate processing apparatus 100A according to the first embodiment. Here, the substrate processing apparatus 100A is a deposition apparatus, which forms a film on substrates W such as semiconductor wafers using the atomic layer deposition (ALD) method by alternately supplying two or more types of processing gases.

The substrate processing apparatus 100A includes a ceilinged cylindrical processing container (reaction tube) 10 with an opening at the bottom thereof. The entire processing container 10 is formed of, for example, quartz.

At the bottom opening of the processing container 10, a metallic flange unit 20 molded in a cylindrical shape is airtightly connected via a seal member such as an O-ring (not illustrated). The flange unit 20 supports the bottom of the processing container 10.

A wafer boat (substrate holder) 30 is inserted into the processing container 10 from below the flange unit 20, in a state of holding a plurality of substrates W (e.g., 25 to 150 substrates) arranged in multiple tiers. In this way, in the processing container 10, the plurality of substrates W are accommodated substantially horizontally while being spaced apart from each other in the vertical direction. The wafer boat 30 is formed of, for example, quartz. The wafer boat 30 includes three rods 31 (of which two are illustrated in FIG. 1), and the plurality of substrates W are supported by grooves (not illustrated) formed in the rods 31.

A metallic lid 32 is provided below the flange unit 20 to open and close the bottom opening of the flange unit 20. The lid 32 is configured to be movable up and down along with the wafer boat 30 by a lift mechanism (not illustrated) such as a boat elevator (not illustrated). A seal member (not illustrated) is provided between the peripheral portion of the lid 32 and the bottom of the flange unit 20 to maintain the airtightness inside the processing container 10.

An insulating body 33 made of quartz is provided between the wafer boat 30 and the lid 32. A rotation mechanism 34 rotates the wafer boat 30 and the insulating body 33 around the vertical axis via a rotary shaft 35. The rotary shaft 35 airtightly penetrates the lid 32 to connect the rotation mechanism 34 and the insulating body 33.

Thus, the wafer boat 30 and the lid 32 move up and down in an integrated body by the lift mechanism, thereby being inserted and removed into/from the processing container 10. Further, the wafer boat 30 rotates around the vertical axis by the rotation mechanism 34. The substrates W may be processed without rotating the wafer boat 30.

A cylindrical heating mechanism 40 is provided around the processing container 10. The processing container 10, the flange unit 20, and the heating mechanism 40 are supported by a base plate 43 extending in the horizontal direction. The heating mechanism 40 includes a ceilinged cylindrical insulating member 41 with an opening at the bottom thereof, and a heater 42 disposed on the inner circumferential surface of the insulating member 41. The heating mechanism 40 heats the processing container 10 by radiant heat from the heater 42 and heat convection. The heating mechanism 40 controls the temperature of the processing container 10 to reach a desired temperature. Accordingly, the substrates W in the processing container 10 are heated by, for example, radiant heat from the wall surface of the processing container 10. That is, the heating mechanism 40 heats the processing container 10 and the substrates W to a desired temperature.

The substrate processing apparatus 100A further includes a gas supply unit 50A that supplies a gas into the processing container 10, and a gas exhaust unit 60A that exhausts a gas from the processing container 10.

Here, the processing container 10 includes a ceilinged cylindrical processing container body 11, a gas supply chamber 12, a pipe (supply-side pipe) 13, and a flange 14.

The processing container body 11 has a ceilinged cylindrical shape, and allows the wafer boat 30 to be inserted thereinto.

The gas supply chamber 12 is formed such that one end side of the lateral surface of the processing container body 11 bulges outwardly while extending along the length direction of the processing container body 11. The interior space of the gas supply chamber 12 communicates with the interior space of the processing container body 11.

The pipe 13 communicates with the gas supply chamber 12 at one end thereof, and extends in the horizontal direction [the radial direction of the processing container body 11] such that the other end thereof extends to the outer circumferential side than the heating mechanism 40. Further, the flange 14 is provided at the other end of the pipe 13.

An injector 200 (200A, 200B) is disposed in the gas supply chamber 12 and the pipe 13.

The gas supply unit 50A includes the injector 200 (200A, 200B), a gas supply source 51, a flow rate regulation unit 52, an opening/closing valve 53, a supply path 54, and a gas injector heater 70.

The gas supply source 51 supplies a gas. The flow rate regulation unit 52 is, for example, a mass flow controller, and regulates the flow rate of the gas supplied from the gas supply source 51. The opening/closing valve 53 switches between the supply of the gas from the gas supply source 51 into the processing container 10 and the stop of the supply. The supply path 54 connects the gas supply source 51 and the pipe 13, and the flow rate regulation unit 52 and the opening/closing valve 53 are disposed in the middle of the supply path 54. The supply path 54 and the pipe 13 are connected to each other outside the heating mechanism 40. Further, the connection portions of the supply path 54 and the pipe 13 are airtightly connected via a seal member 55 such as an O-ring. The injector 200 (200A, 200B) is disposed spanning through the gas supply chamber 12 and the pipe 13. When a gas is supplied through the supply path 54, the injector 200 (200A, 200B) injects the supplied gas into the processing container 10. The gas injector heater 70 heats the pipe 13.

The gas exhaust unit 60A includes an exhaust pipe 25 provided in the side wall of the flange unit 20, a vacuum pump 61, a pressure regulation unit 62, and an exhaust path 63. Accordingly, the gas in the processing container 10 is exhausted to the outside of the processing container 10 by the gas exhaust unit 60A. Further, the pressure in the processing container 10 is controlled to a desired pressure by the pressure regulation unit 62.

The substrate processing apparatus 100A further includes a control unit 80. For example, the control unit 80 controls the operation of each unit of the substrate processing apparatus 100A. The control unit 80 may be, for example, a computer. A storage medium stores a computer program for executing the operation of each unit of the substrate processing apparatus 100A. The storage medium may be, for example, a flexible disk, a compact disk, a hard disk, a flash memory, or a DVD.

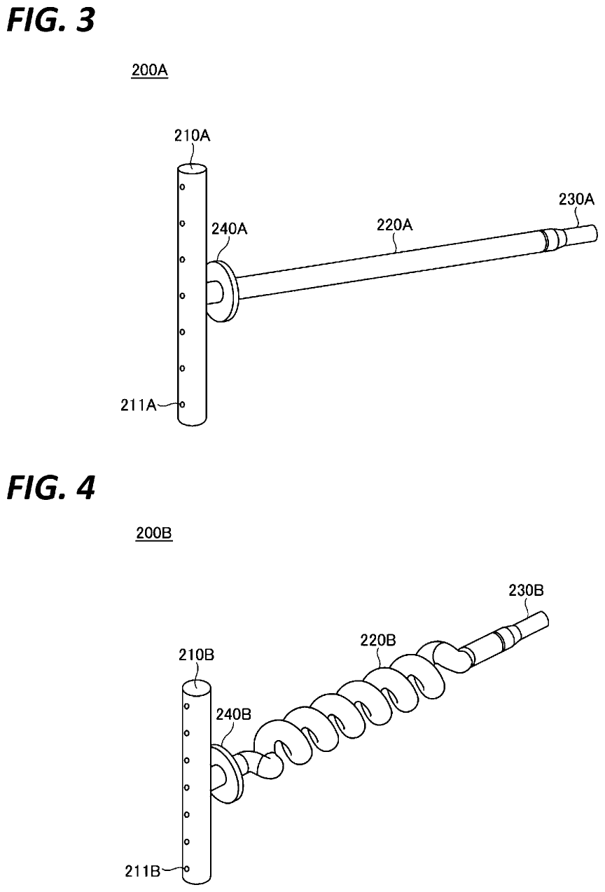

Next, an example of the injector 200 will be described using FIGS. 3 and 4.

FIG. 3 is a perspective view illustrating an example of the injector 200A. The injector 200A includes an injection portion 210A, a transfer portion 220A, a supply portion 230A, and a flange 240A.

The injection portion 210A has a cylindrical shape having an interior space through which a gas may flow, and closed at the upper and lower ends. The injection portion 210A is a pipe disposed inside the gas supply chamber 12 and extends in the height direction of the processing container 10, when the injector 200A is attached to the substrate processing apparatus 100A. In the injection portion 210A, a gas injection hole 211A is formed to communicate with the interior space of the processing container body 11 and the gas supply chamber 12. A plurality of gas injection holes 211A is provided in the injection portion 210A along the height direction of the processing container 10. While the injection portion 210A is described as having the cylindrical shape, the shape of the injection portion 210A is not limited thereto, and may be, for example, a cylindrical shape having the elliptical cross-sectional area or the polygonal cross-sectional area.

The transfer portion 220A is a pipe having the interior space through which a gas may flow. One end of the transfer portion 220A is connected to the injection portion 210A to allow the flow of gas, and the other end thereof is connected to the supply portion 230A to allow the flow of gas. When the injector 200A is attached to the substrate processing apparatus 100A, the transfer portion 220A is disposed inside the pipe 13. Further, while the transfer portion 220A is illustrated as having the cylindrical shape, the shape of the transfer portion 220A is not limited thereto, and may be, for example, a pipe having the elliptical cross-sectional area or the polygonal cross-sectional area.

Here, the transfer portion 220A is formed as a tube having the straight shape (straight-tube shape). As a result, the gas supplied through the supply portion 230A is supplied quickly to the injection portion 210A.

The supply portion 230A is a connection portion connected to the supply path 54, and is supplied with a gas through the supply path 54.

The flange 240A is provided on the outer peripheral surface of the transfer portion 220A, and formed to be substantially the same as (slightly smaller than) the inner diameter of the pipe 13. When the injector 200A is attached to the substrate processing apparatus 100A, the flange 240A is inserted into the pipe 13. As a result, the injector 200A is positioned. Further, the flange 240A blocks the space between the inner peripheral surface of the pipe 13 and the outer peripheral surface of the transfer portion 220A, from the interior space of the processing container body 11 and the gas supply chamber 12. As a result, a high-temperature gas in the interior space of the processing container body 11 and the gas supply chamber 12 is suppressed from flowing into the space between the inner peripheral surface of the pipe 13 and the outer peripheral surface of the transfer portion 220A. In other words, the gas flowing in the injector 200 is suppressed from being heated by a high-temperature gas in the interior space of the processing container body 11 and the gas supply chamber 12. Further, it is possible to reduce the influence on the process for processing substrates, which is caused when the space between the inner peripheral surface of the pipe 13 and the outer peripheral surface of the transfer portion 220A communicates with the interior space of the processing container body 11 and the gas supply chamber 12.

In this way, the gas supplied from the gas supply source 51 flows through the supply path 54, the supply portion 230A, the transfer portion 220A, and the injection portion 210A in this order, and is supplied into the processing container 10 from the gas injection hole 211A.

FIG. 4 is a perspective view illustrating an example of the injector 200B. The injector 200B includes an injection portion 210B, a transfer portion 220B, a supply portion 230B, and a flange 240B.

The injection portion 210B has a cylindrical shape having an interior space through which a gas may flow, and closed at the upper and lower ends. The injection portion 210B is a pipe disposed inside the gas supply chamber 12 and extends in the height direction of the processing container 10, when the injector 200B is attached to the substrate processing apparatus 100A. In the injection portion 210B, a gas injection hole 211B is formed to communicate with the interior space of the processing container body 11 and the gas supply chamber 12. A plurality of gas injection holes 211B is formed in the injection portion 210B along the height direction of the processing container 10. While the injection portion 210B is described as having the cylindrical shape, the shape of the injection portion 210B is not limited thereto, and may be, for example, a cylindrical shape having the elliptical cross-sectional area or the polygonal cross-sectional area.

The transfer portion 220B is a pipe having the interior space through which a gas may flow. One end of the transfer portion 220B is connected to the injection portion 210B to allow the flow of gas, and the other end thereof is connected to the supply portion 230B to allow the flow of gas. When the injector 200B is attached to the substrate processing apparatus 100A, the transfer portion 220B is disposed inside the pipe 13. Further, while the transfer portion 220B is illustrated as having the cylindrical shape, the shape of the transfer portion 220B is not limited thereto, and may be, for example, a pipe having the elliptical cross-sectional area or the polygonal cross-sectional area.

Here, the transfer portion 220B is formed as a tube having the helical (spiral) shape. Thus, it is possible to increase the time for which the gas supplied through the supply portion 230B stays in the transfer portion 220B until transferred to the injection portion 210B. Further, it is possible to expand the contact area between the gas supplied through the supply portion 230B and the inner peripheral surface of the transfer portion 220B until the gas is transferred to the injection portion 210B.

The supply portion 230B is a connection portion connected to the supply path 54, and is supplied with a gas through the supply path 54.

The flange 240B is provided on the outer peripheral surface of the transfer portion 220B, and formed to be substantially the same as (slightly smaller than) the inner diameter of the pipe 13. When the injector 200B is attached to the substrate processing apparatus 100A, the flange 240B is inserted into the pipe 13. As a result, the injector 200B is positioned. Further, the flange 240B blocks the space between the inner peripheral surface of the pipe 13 and the outer peripheral surface of the transfer portion 220B, from the interior space of the processing container body 11 and the gas supply chamber 12. As a result, a high-temperature gas in the interior space of the processing container body 11 and the gas supply chamber 12 is suppressed from flowing into the space between the inner peripheral surface of the pipe 13 and the outer peripheral surface of the transfer portion 220B. In other words, the gas flowing in the injector 200 is suppressed from being heated by a high-temperature gas in the interior space of the processing container body 11 and the gas supply chamber 12. Further, it is possible to reduce the influence on the process for processing substrates, which is caused when the space between the inner peripheral surface of the pipe 13 and the outer peripheral surface of the transfer portion 220B communicates with the interior space of the processing container body 11 and the gas supply chamber 12.

In this way, the gas supplied from the gas supply source 51 flows through the supply path 54, the supply portion 230B, the transfer portion 220B, and the injection portion 210B in this order, and is supplied into the processing container 10 from the gas injection hole 211B.

While the transfer portion 220B of the injector 200B is described as having the helical (spiral) shape, the shape of the transfer portion 220B is not limited thereto. For example, the transfer portion 220B connecting the supply portion 230B and the injection portion 210B may be formed as a plurality of thin pipes to expand the contact area between the transfer portion 220B and the gas. Further, the interior of the supply portion 230B may be formed in a porous shape to expand the contact area between the transfer portion 220B and the gas.

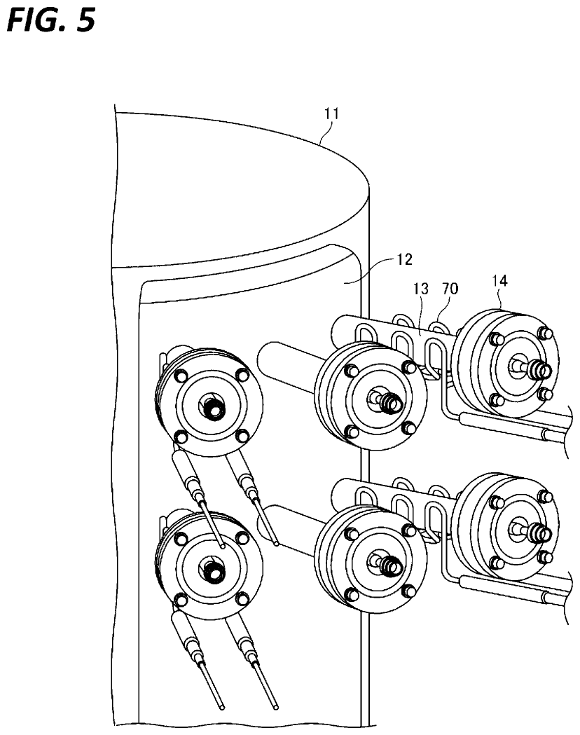

FIG. 5 is a perspective view illustrating an example of the arrangement of the pipe 13 and the gas injector heater 70. The perspective view shows a state where the heating mechanism 40 is removed. The gas supply chamber 12 is provided on the lateral surface of the processing container body 11 to protrude radially outward and extends axially. Further, a plurality of pipes 13 is connected to the gas supply chamber 12 while being arranged in the circumferential direction of the processing container body 11 and in the height direction of the processing container body 11 (the axial direction of the processing container body 11, the inter-plane direction of the plurality of substrates W supported on the wafer boat 30). In the example illustrated in FIG. 5, three pipes 13 are arranged in the circumferential direction, and two pipes 13 are arranged in the height direction.

The gas injector heater 70 may be provided on the outer peripheral side of a pipe 13. In the example illustrated in FIG. 5 (see also, e.g., FIG. 2), the pipes 13 disposed at the right and left sides in the circumferential direction are each provided with the gas injector heater 70. Meanwhile, in the example illustrated in FIG. 5 (see also, e.g., FIGS. 1 and 2), the pipes 3 disposed at the center in the circumferential direction are not provided with the gas injector heater 70.

As illustrated in FIG. 2, the injector 200B may be attached to the pipe 13 provided with the gas injector heater 70 on its outer peripheral side. Meanwhile, the injector 200A may be attached to the pipe 13 provided with no gas injector heater 70 on its outer peripheral side.

The gas injector heater 70 is formed, for example, in a wire shape to enclose the pipe 13 from outside. As illustrated in FIG. 2, the gas injector heater 70 is provided on the outer circumferential side than the heater 42. The gas injector heater 70 may be provided extending to the outer circumferential side than the outer circumferential surface of the insulating member 41. Without being limited to this configuration, the gas injector heater 70 may be provided extending to the inner side than the outer circumferential surface of the insulating member 41. The gas injector heater 70 heats the pipe 13. As the pipe 13 is heated, the transfer portion 220B of the injector 200B disposed inside the pipe 13 is heated by, for example, the radiant heat from the inner peripheral surface of the pipe 13. Then, the gas flowing through the injector 200B is heated by the heated transfer portion 220B.

The transfer portion 220B may be formed in the helical (spiral) shape within the range corresponding to the position of the gas injector heater 70 in the length direction of the pipe 13. Further, the entire transfer portion 220B may be formed in the helical (spiral) shape. Further, a part of the transfer portion 220B disposed on the inner peripheral side than the heater 42 may be formed in the straight-tube shape, and a part of the transfer portion 220B disposed in the range corresponding to the position of the gas injector heater 70 in the length direction of the pipe 13 may be formed in the helical (spiral) shape.

In the transfer portion 220B, a temperature sensor (not illustrated) may be provided to detect the temperature of the transfer portion 220B. The temperature sensor (not illustrated) may be provided on the outer circumferential side than the heater 42. Based on detection values from the temperature sensor of the transfer portion 220B, the control unit 80 may estimate the temperature of the gas supplied into the processing container 10 from the gas injection hole 211B of the injection portion 210B.

Similarly, a temperature sensor (not illustrated) may be provided in transfer portion 220A to detect the temperature of the transfer portion 220A. The temperature sensor (not illustrated) may be provided on the outer circumferential side than the heater 42. Based on detection values from the temperature sensor of the transfer portion 220A, the control unit 80 may estimate the temperature of the gas supplied into the processing container 10 from the gas injection hole 211A of the injection portion 210A.

The same type of gas is supplied to the plurality of pipes 13 arranged in the height direction of the processing container body 11. Meanwhile, different types of gases may be supplied to the pipes 13 arranged in the circumferential direction of the processing container body 11.

For example, assuming that one cycle includes a process of supplying a precursor gas to be adsorbed onto the surfaces of the substrates W into the processing container 10, a process of supplying a purge gas to purge the precursor gas from the processing container 10, a process of supplying a reaction gas (e.g., oxidizing gas or nitriding gas) into the processing container 10 to react with the precursor adsorbed onto the surfaces of the substrates W, and a process of supplying a purge gas to purge the reaction gas from the processing container 10, descriptions will be made on an example of a process for forming a film on the substrates W through the ALD process by repeating the cycle.

For example, a precursor gas is supplied to the pipes 13 at the right side in the circumferential direction. A reaction gas is supplied to the pipes 13 at the left side in the circumferential direction. A purge gas is supplied to the pipes 13 at the center in the circumferential direction. The pipes 13 at the right side in the circumferential direction and the pipes 13 at the left side in the circumferential direction are each provided with the gas injector heater 70.

With this configuration, by controlling each gas injector heater 70, it is possible to vary the temperature of the processing container body 11 heated by the heater 42, the temperature of the precursor gas supplied from the injector 200B into the processing container 10, the temperature of the reaction gas supplied from the injector 200B into the processing container 10, the temperature of the purge gas supplied from the injector 200A into the processing container 10. That is, the temperature of each type of gas supplied into the processing container 10 may be controlled.

As a result, for example, the precursor gas may be supplied into the processing container 10 at a temperature that enables the precursor gas to be appropriately adsorbed onto the surfaces of the substrates W. Further, the reaction gas may be supplied into the processing container 10 at a temperature that enables the reaction gas to appropriately react with the precursor gas adsorbed onto the surfaces of the substrates W. Further, by supplying the purge gas, for example, the substrates W may be cooled.

The pipes 13 are provided extending horizontally from the lateral side of the processing container body 11, so that the gas inside the injector 200 may be suppressed from being heated by the heat from the processing container body 11. This improves the controllability of the temperature of the gas injected from the gas injection holes 211A. 211B.

The same type of gas is supplied from the plurality of pipes 13 into the processing container 10, so that the flow rate and/or the temperature of the gas may be controlled in the height direction. That is, the flow rate and/or the temperature of the gas may be controlled for each region (zone) in the height direction.

In the substrate processing apparatus 100A, the injector 200 (200A, 200B) is configured to be replaceable. Thus, for example, by replacing the current injector 200 with a new different injector 200 in terms of the number of gas injection holes 211A. 211B, the size of each hole, the arrangement of holes, and so on, the shape of the gas supply unit 50A may be changed.

In the substrate processing apparatus 100A according to the first embodiment, the gas supplied into the processing container 10 may be adjusted.

That is, a plurality of regions (zones) is formed in the height direction of the processing container 10. The injector 200 corresponds to each region. In the substrate processing apparatus 100A according to the first embodiment, as illustrated in FIG. 1, the flow rate of the gas supplied to each of the pipes 13 arranged in the height direction may be individually controlled by the flow regulation unit 52. Thus, the flow rate of the gas supplied to each of the plurality of regions may be controlled. Further, each injector 200 is removable. Thus, the flow rate of the gas supplied to each of the plurality of regions may also be controlled by replacing the current injector 200 with a new different injector 200 in terms of, for example, the shape.

In the substrate processing apparatus 100A according to the first embodiment, the temperature of a gas supplied may be controlled individually by controlling the gas injector heater 70 provided to correspond to each of the pipes 13 arranged in the height direction. As a result, the temperature of the gas supplied to each of the plurality of regions may be controlled.

In the substrate processing apparatus 100A according to the first embodiment, the flow rate and the temperature of a gas supplied may be controlled for each type of gas and each region.

The gas supplied into the processing container 10 from the gas injection holes 211A, 211B passes through the spaces among the substrates W supported on the wafer boat 30, and is exhausted to the outside of the processing container 10 through the exhaust pipe 25. Thus, the uniformity of the flow rate and the temperature of the gas supplied by the side flow may be improved, so that the uniformity of the substrate processing may be improved.

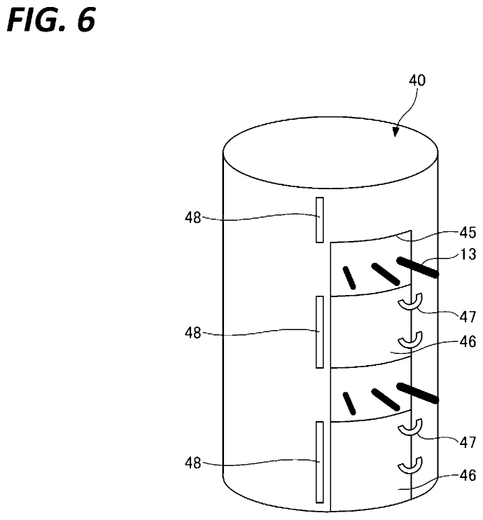

Next, an example of the structure of the heating mechanism 40 will be further described using FIG. 6. FIG. 6 is a perspective view illustrating an example of the structure of the heating mechanism 40. On the processing container 10, the plurality of pipes 13 are provided to extend radially outward.

The heating mechanism 40 has a ceilinged cylindrical shape with an opening at the bottom thereof. Further, in the side wall of the heating mechanism 40 that corresponds to the position where the pipes 13 are arranged, a notch 45 is formed to extend from the bottom of the heating mechanism 40. The notch 45 communicates with the opening at the bottom of the heating mechanism 40. Thus, the processing container 10 having the pipes 13 is inserted into the heating mechanism 40 from the opening at the bottom of the heating mechanism 40, with the pipes 13 passing through the notch 45. An arc-shaped partial heating unit 46 is disposed between the pipes 13 arranged vertically to cover a portion of the notch 45. A heater (not illustrated) provided in the partial heating unit 46 is connected to the heater 42 of the heating mechanism 40 via a harness 47. With this configuration, when power is supplied from a heater terminal 48, the power may be fed to the heater 42 of the heating mechanism 40 and the heater (not illustrated) of the partial heating unit 46. An insulating member is provided in the portion of the notch 45 around the pipes 13 that is not covered by the partial heating unit 46.

In this way, even when the processing container 10 includes the plurality of pipes 13 extending radially outward, the heating mechanism 40 may be provided on the outer peripheral side of the processing container 10.

While descriptions have been made on a case where the gas injector heater 70 is provided on the outer side of the pipe 13 to heat the gas, the present disclosure is not limited thereto. A cooling device (not illustrated) may be provided on the outer side of the pipe 13 to cool the pipe 13, thereby cooling the gas. The cooling device has a flow path through which a refrigerant may flow, and is connected to a chiller (not illustrated) such that a low-temperature refrigerant is supplied from the chiller to the cooling device to cool the pipe 13. As a result, the transfer portion 220B of the injector 200 is cooled. Then, the gas flowing through the transfer portion 220B is cooled.

### [Substrate Processing Apparatus 100B According to Second Embodiment]

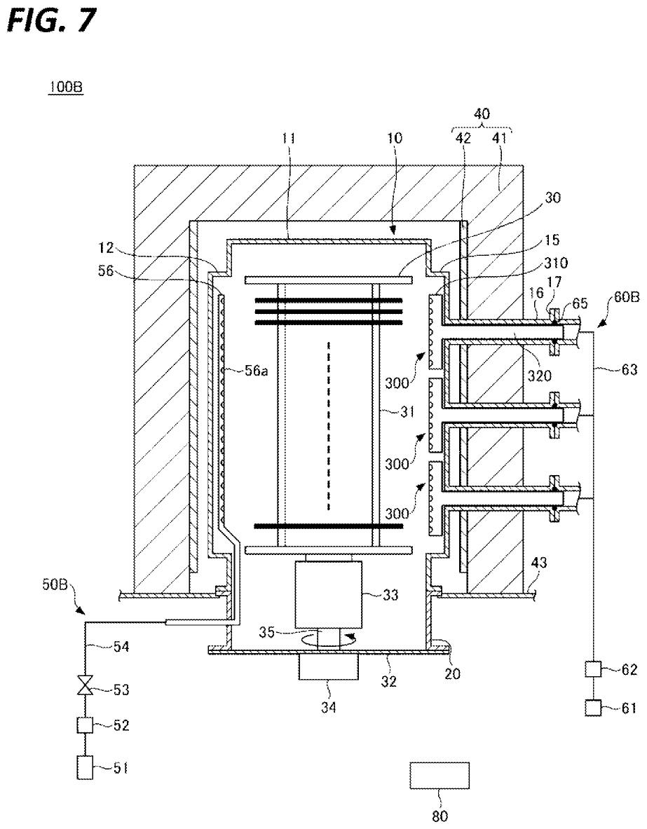

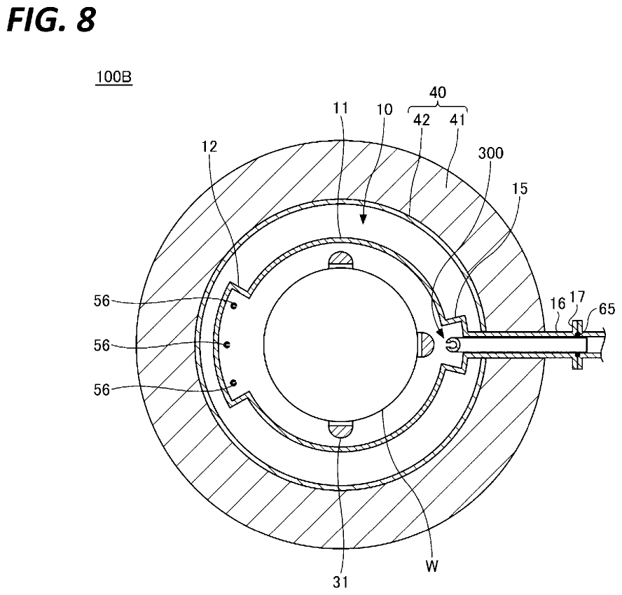

A substrate processing apparatus 100B according to a second embodiment will be described using FIGS. 7 and 8. FIG. 7 is a vertical cross-sectional view illustrating an example of the substrate processing apparatus 100B according to the second embodiment. FIG. 8 is a horizontal cross-sectional view illustrating an example of the substrate processing apparatus 100B according to the second embodiment. Here, the substrate processing apparatus 100B is a deposition apparatus, which forms a film on substrates W such as semiconductor wafers using the atomic layer deposition (ALD) method by alternately supplying two or more types of processing gases.

The substrate processing apparatus 100B includes a ceilinged cylindrical processing container (reaction tube) 10 with an opening at the bottom thereof. The entire processing container 10 is formed of, for example, quartz.

At the bottom opening of the processing container 10, a metallic flange unit 20 molded in a cylindrical shape is airtightly connected via a seal member such as an O-ring (not illustrated). The flange unit 20 supports the bottom of the processing container 10.

A wafer boat (substrate holder) 30 is inserted into the processing container 10 from below the flange unit 20, in a state of holding a plurality of substrates W (e.g., 25 to 150 substrates) arranged in multiple tiers. In this way, in the processing container 10, the plurality of substrates W are accommodated substantially horizontally while being spaced apart from each other in the vertical direction. The wafer boat 30 is formed of, for example, quartz. The wafer boat 30 includes three rods 31 (of which two are illustrated in FIG. 7), and the plurality of substrates W are supported by grooves (not illustrated) formed in the rods 31.

A metallic lid 32 is provided below the flange unit 20 to open and close the bottom opening of the flange unit 20. The lid 32 is configured to be movable up and down along with the wafer boat 30 by a lift mechanism (not illustrated) such as a boat elevator (not illustrated). A seal member (not illustrated) is provided between the peripheral portion of the lid 32 and the bottom of the flange unit 20 to maintain the airtightness inside the processing container 10.

An insulating body 33 made of quartz is provided between the wafer boat 30 and the lid 32. A rotation mechanism 34 rotates the wafer boat 30 and the insulating body 33 around the vertical axis via a rotary shaft 35. The rotary shaft 35 airtightly penetrates the lid 32 to connect the rotation mechanism 34 and the insulating body 33.

Thus, the wafer boat 30 and the lid 32 move up and down in an integrated body by the lift mechanism, thereby being inserted and removed into/from the processing container 10. Further, the wafer boat 30 rotates around the vertical axis by the rotation mechanism 34. The substrates W may be processed without rotating the wafer boat 30.

A cylindrical heating mechanism 40 is provided around the processing container 10. The processing container 10, the flange unit 20, and the heating mechanism 40 are supported by the base plate 43 extending in the horizontal direction. The heating mechanism 40 includes a ceilinged cylindrical insulating member 41 with an opening at the bottom thereof, and a heater 42 disposed on the inner circumferential surface of the insulating member 41. The heating mechanism 40 heats the processing container 10 by radiant heat from the heater 42 and heat convection. The heating mechanism 40 controls the temperature of the processing container 10 to reach a desired temperature. Accordingly, the substrates W in the processing container 10 are heated by, for example, radiant heat from the wall surface of the processing container 10. That is, the heating mechanism 40 heats the processing container 10 and the substrates W to a desired temperature.

The substrate processing apparatus 100B further includes a gas supply unit 50B that supplies a gas into the processing container 10, and a gas exhaust unit 60B that exhausts a gas from the processing container 10.

Here, the processing container 10 includes a ceilinged cylindrical processing container body 11, a gas supply chamber 12, a gas exhaust chamber 15, a pipe (exhaust-side pipe) 16, and a flange 17.

The processing container body 11 has a ceilinged cylindrical shape, and allows the wafer boat 30 to be inserted thereinto.

The gas supply chamber 12 is formed such that one end side of the lateral surface of the processing container body 11 bulges outwardly while extending along the length direction of the processing container body 11. The interior space of the gas supply chamber 12 communicates with the interior space of the processing container body 11.

The gas exhaust chamber 15 is formed such that the other end side of the lateral surface of the processing container body 11 bulges outwardly along the length direction of the processing container body 11. The interior space of the gas exhaust chamber 15 communicates with the interior space of the processing container body 11.

The pipe 16 communicates with the gas exhaust chamber 15 at one end thereof, and extends in the horizontal direction [the diameter direction of the processing container body 11] such that the other end thereof extends to the outer circumferential side than the heating mechanism 40. Further, the flange 17 is provided at the other end of the pipe 16.

An ejector 300 is provided in the gas exhaust chamber 15 and the pipe 16.

The gas supply unit 50B includes a gas supply source 51, a flow rate regulation unit 52, an opening/closing valve 53, a supply path 54, and a gas supply pipe 56.

The gas supply source 51 supplies a gas. The flow rate regulation unit 52 is, for example, a mass flow controller, and regulates the flow rate of the gas supplied by the gas supply source 51. The opening/closing valve 53 switches between the supply of the gas from the gas supply source 51 into the processing container 10 and the stop of the supply. The supply path 54 connects the gas supply source 51 and the gas supply pipe 56, and the flow rate regulation unit 52 and the opening/closing valve 53 are disposed in the middle of the supply path 54. The gas supply pipe 56 is inserted into the processing container 10 through the flange unit 20, and disposed in the gas supply chamber 12. The gas supply pipe 56 has a plurality of injection holes 56a formed in the height direction.

The gas exhaust unit 60B includes the ejector 300, a vacuum pump 61, a pressure regulation unit 62, and an exhaust path 63. Accordingly, the gas in the processing container 10 is exhausted to the outside of the processing container 10 by the gas exhaust unit 60B. Further, the pressure in the processing container 10 is controlled to a desired pressure by the pressure regulation unit 62. The pipe 16 and the exhaust path 63 are connected to each other outside the heating mechanism 40. Further, the connection portions of the pipe 16 and the exhaust path 63 are airtightly connected via a seal member 65 such as an O-ring. The ejector 300 is disposed spanning through the gas exhaust chamber 15 and the pipe 16.

The substrate processing apparatus 100B further includes a control unit 80. For example, the control unit 80 controls the operation of each unit of the substrate processing apparatus 100B. The control unit 80 may be, for example, a computer. A storage medium stores a computer program for executing the operation of each unit of the substrate processing apparatus 100B. The storage medium may be, for example, a flexible disk, a compact disk, a hard disk, a flash memory, or a DVD.

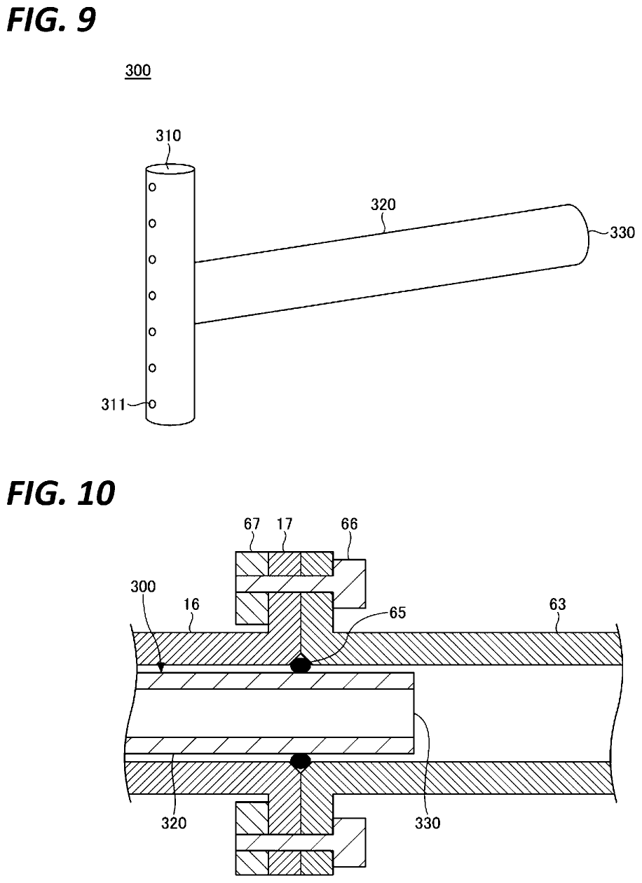

Next, an example of the ejector 300 will be described using FIG. 9.

FIG. 9 is a perspective view illustrating an example of the ejector 300. The ejector 300 includes a suction portion 310, a transfer portion 320, and an ejection portion 330.

The suction portion 310 has a cylindrical shape having an interior space through which a gas may flow, and closed at the upper and lower ends. The suction portion 310 is a pipe disposed inside the gas exhaust chamber 15 and extends in the height direction of the processing container 10, when the ejector 300 is attached to the substrate processing apparatus 100B. In the suction portion 310, a gas suction hole 311 is formed to communicate with the interior space of the processing container body 11 and the gas exhaust chamber 15. A plurality of gas suction holes 311 is formed in the suction portion 310 along the height direction of the processing container 10. While the suction portion 310 is described as having the cylindrical shape, the shape of the suction portion 310 is not limited thereto, and may be, for example, a cylindrical shape having the elliptical cross-sectional area or the polygonal cross-sectional area.

The transfer portion 320 is a pipe having the interior space through which a gas may flow. One end of the transfer portion 320 is connected to the suction portion 310 to allow the flow of gas, and the other end thereof is connected to the ejection portion 330 to allow the flow of gas. When the ejector 300 is attached to the substrate processing apparatus 100B, the transfer portion 320 is disposed inside the pipe 16. Further, while the transfer portion 320 is illustrated as having the cylindrical shape, the shape of the transfer portion 320 is not limited thereto, and may be, for example, a pipe having the elliptical cross-sectional area or the polygonal cross-sectional area.

Here, the transfer portion 320 is formed in a straight-tube shape. As a result, the gas sucked from the gas suction hole 311 of the suction portion 310 passes through the straight tube-shaped transfer portion 320, and is exhausted quickly to the ejection portion 330.

The ejection portion 330 is a connection portion connected to the exhaust path 63, and exhausts a gas to the exhaust path 63.

In this way, the gas in the processing container 10 flows through the gas suction

hole 311, the suction portion 310, the transfer portion 320, and the ejection portion 330 in this order, and is exhausted to the exhaust path 64.

FIG. 10 is a cross-sectional view illustrating an example of the seal structure of the pipe 16, the ejector 300, and the exhaust path 63.

The pipe 16 and the exhaust path 63 are connected in the manner that the flange 17 provided at the other end of the pipe 16 and the flange provided at one end of the exhaust path 63 are in contact with each other, and fastened by bolts 66 and nuts 67. The ejection portion 330 of the ejector 300 is inserted through the pipe 16 and enters even the inside of the exhaust path 63. The seal member 65 implements the sealing by being in contact with the pipe 16, the ejector 300, and the exhaust path 63.

The flow passage cross-sectional area (e.g., the inner diameter) of the exhaust path 63 is larger than the flow passage cross-sectional area (e.g., the inner diameter) of the transfer portion 320 and the ejection portion 330 of the ejector 300. Thus, the exhaust may be performed appropriately.

As a result, the gas in the processing container 10 is exhausted through the gas suction hole 311 of the ejector 300.

In the substrate processing apparatus 100B, the ejector 300 is configured to be replaceable. Thus, for example, by replacing the current ejector 300 with a new different ejector 300 in terms of the number of gas suction holes 311, the size of each hole, the arrangement of holes, and so on, the shape of the gas exhaust unit 60B may be changed.

In the substrate processing apparatus 100B according to the second embodiment, the flow rate of the gas exhausted from the processing container 10 may be adjusted.

That is, a plurality of regions (zones) is formed in the height direction of the processing container 10. The ejector 300 corresponds to each region. In the substrate processing apparatus 100B according to the second embodiment, as illustrated in FIG. 7, the flow rate of the gas exhausted from each of the pipes 16 arranged in the height direction may be controlled by the ejector 300. Further, the ejector 300 is removable. Thus, the flow rate of the gas exhausted from each of the plurality of regions may be controlled by replacing the current ejector 300 with a new different ejector 300 in terms of, for example, the shape.

Thus, the gas supplied into the processing container 10 from the injection units 56a of the gas supply pipe 56 passes the spaces among the substrates W supported on the wafer boat 30, and is exhausted to the outside of the processing container 10 through the gas suction hole 311. As a result, the uniformity of the gas supplied by the side flow may be improved, so that the uniformity of the substrate processing may be improved.

### [Substrate Processing Apparatus 100C According to Third Embodiment]

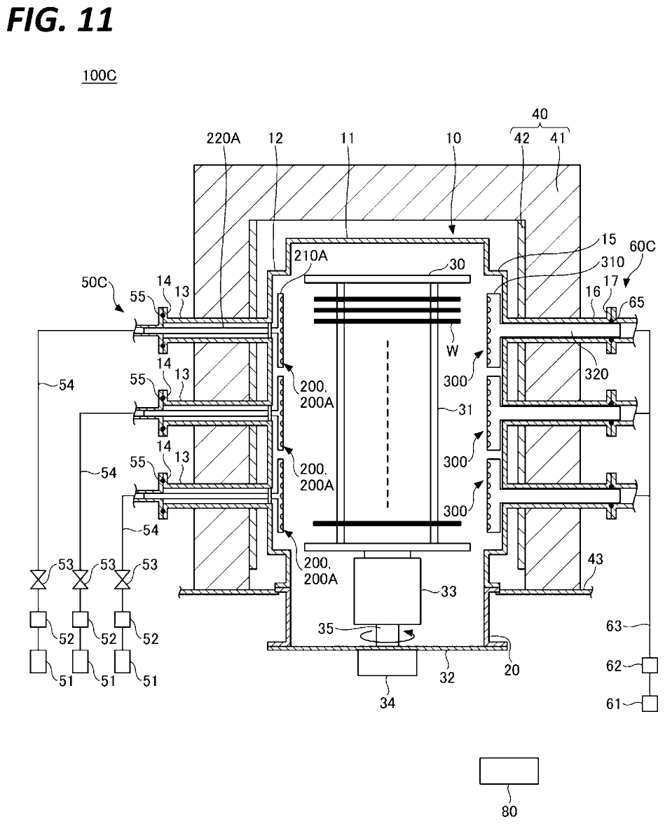

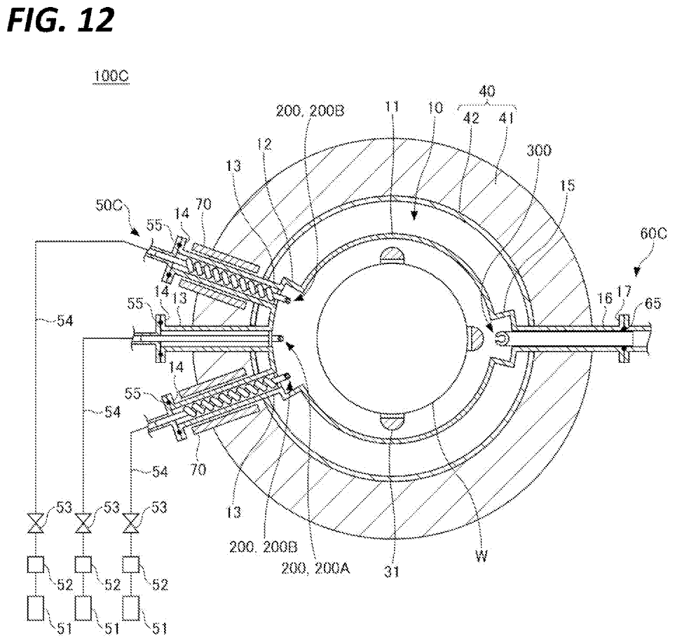

A substrate processing apparatus 100C according to a third embodiment will be described using FIGS. 11 and 12. FIG. 11 is a vertical cross-sectional view illustrating an example of the substrate processing apparatus 100C according to the third embodiment. FIG. 12 is a horizontal cross-sectional view illustrating an example of the substrate processing apparatus 100C according to the third embodiment. Here, the substrate processing apparatus 100C is a deposition apparatus, which forms a film on substrates W such as semiconductor wafers using the atomic layer deposition (ALD) method by alternately supplying two or more types of processing gases.

Here, the processing container 10 includes a ceilinged cylindrical processing container body 11, a gas supply chamber 12, a pipe 13, a flange 14, a gas exhaust chamber 15, a pipe 16, and a flange 17. The substrate processing apparatus 100C further includes a gas supply unit 50C that supplies a gas into the processing container 10, and a gas exhaust unit 60C that exhausts a gas from the processing container 10. The gas supply unit 50C has the same configuration as the gas supply unit 50A (see, e.g., FIGS. 1 to 6). The gas exhaust unit 60C has the same configuration as the gas exhaust unit 60B (see, e.g., FIGS. 7 to 10). The other configurations of the substrate processing apparatus 100C are the same as those of the substrate processing apparatuses 100A and 100B, and overlapping descriptions will be omitted.

Here, the flow passage cross-sectional area of the ejector 300 may be larger than the flow passage cross-sectional area of the injector 200 (200A, 200B). That is, the flow passage cross-sectional area, which is taken by horizontally cutting the interior space of the suction portion 310, may be larger than the flow passage cross-sectional area, which is taken by horizontally cutting the interior space of the injection portion 210A, 210B. The flow passage cross-sectional area of the transfer portion 320 may be larger than the flow passage cross-sectional area of the transfer portion 220A, 220B. The flow passage cross-sectional area of the ejection portion 330 may be larger than the flow passage cross-sectional area of the supply portion 230A, 230B. The diameter of the gas ejection hole 311 may be larger than the diameter of the gas injection hole 211A, 211B.

In the substrate processing apparatus 100C according to the third embodiment, the gas supplied into the processing container 10 may be adjusted.

That is, a plurality of regions (zones) is formed in the height direction of the processing container 10. The injector 200 corresponds to each region. In the substrate processing apparatus 100C according to the third embodiment, the flow rate of the gas supplied to each of the pipes 13 arranged in the height direction may be individually controlled by the flow regulation unit 52. Thus, the flow rate of the gas supplied to each of the plurality of regions may be controlled. Further, the injector 200 is removable. Thus, the flow rate of the gas supplied to each of the plurality of regions may also be controlled by replacing the current injector 200 with a new different injector 200 in terms of, for example, the shape.

In the substrate processing apparatus 100C according to the third embodiment, the temperature of the gas supplied may be individually controlled by independently controlling the gas injector heater 70 provided to correspond to each of the pipes 13 arranged in the height direction. Thus, the temperature of the gas supplied to each of the plurality of regions may be controlled.

In the substrate processing apparatus 100C according to the third embodiment, the flow rate and the temperature of the gas supplied may be controlled for each type of gas and each region.

In the substrate processing apparatus 100C according to the third embodiment, the flow rate of the gas exhausted from the processing container 10 may be adjusted.

That is, a plurality of regions (zones) is formed in the height direction of the processing container 10. The ejector 300 corresponds to each region. In the substrate processing apparatus 100C according to the third embodiment, the flow rate of the gas exhausted from each of the pipes 13 arranged in the height direction may be controlled by the ejector 300. Further, the ejector 300 is removable. Thus, the flow rate of the gas exhausted from each of the plurality of regions may be controlled by replacing the current ejector 300 with a new different ejector 300 in terms of, for example, the shape.

Thus, the gas supplied into the processing container 10 from the gas injection hole 211A, 211B passes the spaces among the substrates W supported on the wafer boat 30, and is exhausted to the outside of the processing container 10 through the gas suction hole 311. Therefore, the uniformity of the gas supplied by the side flow may be improved, so that the uniformity of the substrate processing may be improved.

According to an aspect of the present disclosure, it is possible to provide a substrate processing apparatus capable of adjusting a gas supplied into a processing container.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a processing container configured to accommodate a substrate holder that holds substrates;
a gas supply chamber provided in a side wall of the processing container;
a supply-side pipe extending horizontally from the gas supply chamber; and
an injector detachably disposed spanning through the gas supply chamber and the supply-side pipe.

2. The substrate processing apparatus according to claim 1, further comprising:
a heater accommodating the processing container,
wherein the supply-side pipe penetrates a side surface of the heater.

3. The substrate processing apparatus according to claim 1, wherein a plurality of supply-side pipes is provided in an axial direction of the processing container.

4. The substrate processing apparatus according to claim 3, wherein a same type of gas is supplied to a plurality of injectors provided corresponding to the plurality of supply-side pipes arranged in the axial direction of the processing container, respectively.

5. The substrate processing apparatus according to claim 1, wherein a plurality of supply-side pipes is provided in a circumferential direction of the processing container.

6. The substrate processing apparatus according to claim 5, wherein different types of gases are supplied to a plurality of injectors provided corresponding to the plurality of supply-side pipes arranged in the circumferential direction of the processing container, respectively.

7. The substrate processing apparatus according to claim 6, further comprising:
a gas injector heater that heats each of the plurality of supply-side pipes.

8. The substrate processing apparatus according to claim 1, wherein the injector includes
an injection portion having a plurality of gas injection holes, and
a transfer portion communicating with the injection portion, and disposed inside the supply-side pipe.

9. The substrate processing apparatus according to claim 8, wherein the transfer portion has a straight tube shape.

10. The substrate processing apparatus according to claim 8, wherein the transfer portion has a spiral tube shape.
